(19) United States
(12) Patent Application Publication
(10) Pub. No.: US 2023/0258747 A1
(43) Pub. Date: Aug. 17, 2023

(54) Composite Hard Masks For Ultra-Thin Magnetic Sensors

(71) Applicant: Headway Technologies, Inc., Milpitas, CA (US)

(72) Inventors: Tom Zhong, Saratoga, CA (US); Min Li, Fremont, CA (US); Ruhang Ding, Pleasanton, CA (US); Hiroshi Omine, Santa Clara, CA (US); QingJun Qin, Dublin, CA (US); Richard Zhou, Fremont, CA (US); Yunqing Cai, San Jose, CA (US); Yewhee Chye, Hayward, CA (US); Minghui Yu, Fremont, CA (US)

(21) Appl. No.: 17/671,413

(22) Filed: Feb. 14, 2022

(51) Int. Cl. G01R 33/09; H01F 10/32; G03F 7/42; G03F 7/16; G03F 7/36; B24B 37/04

(52) U.S. Cl. CPC G01R 33/093; H01F 10/3272; H01F 10/3254; G03F 7/427; G03F 7/16; G03F 7/36; B24B 37/042; B24B 37/048

(57) ABSTRACT

A composite hard mask is disclosed. In some embodiments, a first sacrificial hard mask layer comprising an amorphous carbon or silicon nitride and a second sacrificial hard mask layer comprising a silicon nitride, silicon oxide, metal, metal oxide, or metal nitride, wherein the first and second sacrificial hard mask layers are not made of the same material.

### TECHNICAL FIELD

Embodiments of the present disclosure relate generally to magnetic sensors such as magnetoresistive (MR) sensors. More specifically, embodiments of the present disclosure relate to composite hard masks for making ultra-thin magnetic sensors such as MR sensors.

### BACKGROUND

One of the major challenges in the hard disk drive (HDD) industry is to make magnetic sensors such as MR sensors that have ultra-fine critical dimension (CD), e.g., 20 nm or less, and ultra-thin in total sensor film stack thickness, e.g., 15 nm or less, to meet the demand for higher areal density data recording. Conventional fabrication process schemes for MR sensors do not allow for the scaling down of MR sensor size and thickness.

Therefore, there is a need for an improvised composite hard mask and fabrication process to significantly improve the scalability of MR sensors, i.e., the scaling down of MR sensor size and thickness.

### SUMMARY

Broadly, embodiments of the present disclosure provide an improved composite hard mask. According to some embodiments of the present disclosure, the improved composite hard mask can include a first sacrificial hard mask layer comprising an amorphous carbon or silicon nitride; and a second sacrificial hard mask layer comprising a silicon nitride, silicon oxide, metal, metal oxide, or metal nitride, wherein the first and second sacrificial hard mask layers are not made of the same material.

According to some embodiments of the present disclosure, the first sacrificial hard mask layer can be an amorphous carbon masking layer.

According to some embodiments of the present disclosure, the first sacrificial hard mask layer can be a silicon nitride masking layer.

According to some embodiments of the present disclosure, the second sacrificial hard mask layer can comprise Ti, Ta, NiCr, NiFe, TaOₓ, SmOₓ, Al₂O₃, SiO₂, or SiN.

According to some embodiments of the present disclosure, the second sacrificial hard mask layer is made from material that can be removed without affecting the first sacrificial hard mask layer.

According to some embodiments of the present disclosure, the first sacrificial hard mask layer can comprise amorphous carbon and the second sacrificial hard mask layer can comprise SiO₂, NiFe, NiCr, SiN, Ti, TaOₓ, or SmOₓ.

According to some embodiments of the present disclosure, the first sacrificial hard mask layer can comprise SiN and the second sacrificial hard mask layer can comprise Al₂O₃, or SiO₂.

According to some embodiments of the present disclosure, a thickness of the first sacrificial hard mask layer can be 10 to 150 Angstroms.

According to some embodiments of the present disclosure, a thickness of the second sacrificial hard mask layer can be 20 to 800 Angstroms.

According to some embodiments of the present disclosure, a thickness of the first sacrificial hard mask layer can be less than a thickness of the second sacrificial hard mask layer.

Also disclosed herein is a film stack structure that includes the improved composite hard mask. According to some embodiments of the present disclosure, the film stack structure can include a bottom electrode.

According to some embodiments of the present disclosure, the film stack structure further can include a seed layer, an anti-ferromagnetic (AFM) pinning layer, a ferromagnetic pinned layer, a coupling layer, a reference layer, a spacer or barrier layer, a ferromagnetic free layer, and a capping layer sequentially formed on the bottom electrode.

According to some embodiments of the present disclosure, the pinned layer, the coupling layer, and the reference layer 106 can form a synthetic anti-parallel (SyAP) layer.

According to some embodiments of the present disclosure, the composite hard mask can be formed on the capping layer.

Also disclosed herein is a method of forming a MR sensor. According to some embodiments of the present disclosure, the method includes providing the film stack structure with the improved composite hard mask.

According to some embodiments of the present disclosure, the method can include sequentially coating a bottom anti-reflective coating (BARC) and a photoresist layer on the composite hard mask.

According to some embodiments of the present disclosure, the method can include a MR junction photopatterning including patterning the photoresist layer and transferring a photoresist pattern through the BARC.

According to some embodiments of the present disclosure, the method can include patterning the first and second hard mask layers by dry reactive ion etching (RIE), ion beam etching (IBE), or a combination of both methods.

According to some embodiments of the present disclosure, the method can include forming a MR junction after patterning of the first and second hard sacrificial mask layers.

According to some embodiments of the present disclosure, forming the MR junction can include ion beam etching (IBE) to pattern the MR junction.

According to some embodiments of the present disclosure, ion beam etching (IBE) to pattern the MR junction can stop between a seed layer and a capping layer of the film stack structure.

According to some embodiments of the present disclosure, ion beam etching (IBE) to pattern the MR junction can stop at or within a spacer or barrier layer of the film stack structure.

According to some embodiments of the present disclosure, the method can further include depositing a layer of insulating material after forming the MR junction.

According to some embodiments of the present disclosure, the method can further include ion beam etching (IBE) after depositing the layer of insulating material to open up sidewalls around the MR junction and expose the photoresist layer.

According to some embodiments of the present disclosure, the method can further include removing the BARC and the photoresist layer.

According to some embodiments of the present disclosure, the method can further include applying a chemical mechanical polishing (CMP) process to planarize a wafer surface after removing the BARC and the photoresist layer.

According to some embodiments of the present disclosure, the first sacrificial hard mask layer can be configured to serve as a CMP stop layer.

According to some embodiments of the present disclosure, the method can further include applying an etch back process to remove the first sacrificial hard mask layer.

### BRIEF DESCRIPTION OF THE DRAWINGS

The accompanying drawings, which are incorporated in and constitute a part of this specification, exemplify various embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not generally drawn to scale.

FIGS. 1(a)-(d) show a conventional fabrication process scheme of a MR sensor.

FIG. 2(a) shows a film stack structure including the improved composite hard mask according to some embodiments of the present disclosure. FIG. 2(b) shows a simplified version of the film stack structure according to some embodiments of the present disclosure.

FIG. 3 (a)-(g) illustrate a method of forming a MR sensor according to some embodiments of the present disclosure. The illustrated film stack structure is based on the simplified version of the film stack structure according to some embodiments of the present disclosure.

FIGS. 4(a)-(e) illustrate another method of forming a MR sensor according to some embodiments of the present disclosure. The illustrated film stack structure is based on the simplified version of the film stack structure according to some embodiments of the present disclosure.

FIGS. 5(a)-(g) illustrate an additional of forming a MR sensor according to some embodiments of the present disclosure. The illustrated film stack structure is based on the simplified version of the film stack structure according to some embodiments of the present disclosure.

### DETAILED DESCRIPTION

A composite hard mask is disclosed herein is disclosed herein. The composite hard mask allows for an improved process integration scheme to effectively address the local dishing and long-tail issues caused in the conventional process integration scheme. As a result, the scalability of MR sensors can be significantly improved, i.e., the scaling down of MR sensor size and thickness can be significantly improved.

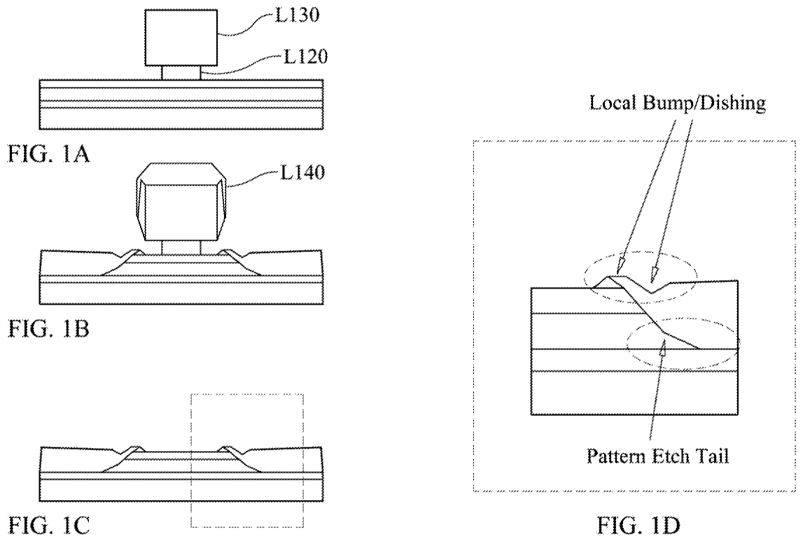

FIG. 1 shows a conventional fabrication process scheme of a MR sensor. A typical liftoff process is normally applied to fabricate in conventional process integration scheme. In this scheme, a magnetic films stack is first deposited on top of a pre-patterned bottom electrode. This bottom electrode is often made of magnetic materials and often serves as a magnetic shield and prevents any magnetic field disturbance from sensor bottom layers. After magnetic film stack deposition, a photopattern with undercut as shown in FIG. 1(a) is applied. In FIG. 1(a), L120 is normally a bottom anti-reflective layer (BARC) and L130 is a photoresist layer. After photopatterning, an ion beam etching (IBE) process is often applied to form the sensor junction device. After IBE etch, it is then often followed with ion beam deposition (IBD) of dielectric films (L140) as shown in FIG. 1(b) to insulate junction devices from surroundings. After ion beam deposition, a liftoff process using hot n-methyl pyrrolidinone (NMP) is often applied to remove deposition materials from the areas covered by resist patterns as shown in FIG. 1(c). After liftoff process, a magnetic sensor device is formed and ready for top electrode patterning processes.

Referring to FIG. 1(d), there are two commonly observed issues in the conventional fabrication process scheme of a MR sensor. A first issue is that a local bump (or protrusion) at the sensor pattern edge is formed by the IBE/IBD processes and a local dishing is created by resist pattern shadowing effect during IBD deposition. A second issue is that a tail at a device bottom is formed by the photoresist undercut pattern and its shadowing effect during the IBE process as shown in FIG. 1(d). The topographies by the local dishing and local bumps can not only affect the sensor performance but also create challenges for subsequent layer processes. The length of the tail is difficult to control due to the difficulty of the precise shape of a photo pattern with undercut. This tail length variation can cause significant sensor to sensor performance variation. As MR sensor size and thickness decreases, these negative effects from these issues related to MR sensor performances become more and more prominent. In other words, conventional integration schemes limit the scaling down of MR sensor size and thickness.

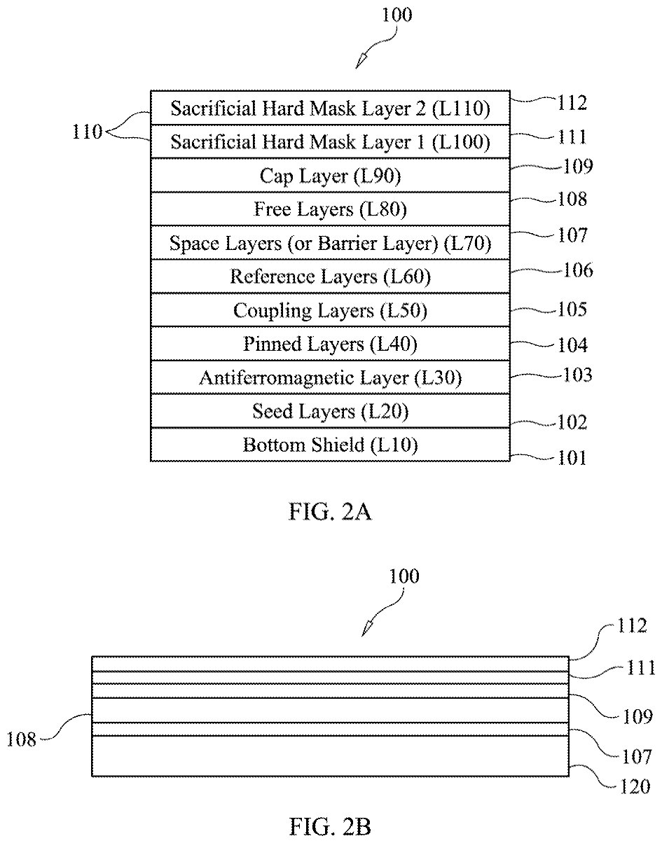

FIG. 2(a) shows a film stack structure 100 including the improved composite hard mask according to some embodiments of the present disclosure. As discussed above, the composite hard mask allows for an improved process integration scheme to effectively address the local dishing and long-tail issues caused in the conventional process integration scheme. As a result, the scalability of MR sensors can be significantly improved, i.e., the scaling down of MR sensor size and thickness can be significantly improved.

In some embodiments, the film stack structure 100 includes a bottom electrode 101. The bottom electrode layer 52 may be a composite layer made of conductive materials as appreciated by those skilled in the art. In some embodiments, the bottom electrode 101 is a pre-patterned bottom electrode.

In some embodiments, the film stack structure 100 can further include a seed layer 102, an anti-ferromagnetic (AFM) pinning layer 103, a ferromagnetic pinned layer 104, a coupling layer 105, a reference layer 106, a spacer or barrier layer 107, a ferromagnetic free layer 108, and a capping layer 109 sequentially formed on the bottom electrode 101. FIG. 2(b) shows a simplified version of the film stack structure 100 according to some embodiments of the present disclosure. Specifically, the bottom electrode 101, seed layer 102, anti-ferromagnetic (AFM) pinning layer 103, ferromagnetic pinned layer 104, coupling layer 105, and reference layer 106 are combined into one layer 120.

In some embodiments, the seed layer 102 can be made of any material as appreciated by those skilled in the art. In some embodiments, the seed layer can be made from Ta, TaRu, Ta/NiCr, Ta/Cu, Ta/Cr, or other suitable seed layer materials. The seed layer 102 serves to promote a smooth and uniform grain structure in overlying layers.

In some embodiments, above the seed layer 102 is an anti-ferromagnetic (AFM) pinning layer 103 used to pin the magnetization direction of the overlying pinned layer 104. In some embodiments, the AFM layer 103 has a thickness from 40 to 300 Angstroms and can be made of any material as appreciated by those skilled in the art. In some embodiments, the anti-ferromagnetic (AFM) pinning layer 103 can be made of MnPt, IrMn, NiMn, OsMn, RuMn, RhMn, PdMn, RuRhMn, or MnPtPd.

In some embodiments, the pinned layer 104, the coupling layer 105, and the reference layer 106 preferably have a synthetic anti-parallel (SyAP) configuration represented by AP2/coupling layer/AP1 where the coupling layer 105 is sandwiched between an AP2 layer and an AP1 layer (not shown). In other words, in some embodiments, the pinned layer 104, the coupling layer 105, and the reference layer 106 form a SyAP pinned layer. In some embodiments, the coupling layer 105 can be made of any material as appreciated by those skilled in the art. In some embodiments, the coupling layer 105 is a layer of Ru, Rh or Cr. In some embodiments, the AP2 pinned layer 104, which is also referred to as the outer pinned layer, contacts the AFM layer 103 and may be made of CoFe. The AP2 layer (pinned layer 104) also can be made of any other suitable material as appreciated by those skilled in the art. The magnetic moment of the AP2 layer is pinned in a direction anti-parallel to the magnetic moment of the AP1 layer. For example, the AP2 layer may have a magnetic moment oriented along the “+x” direction while the AP1 layer has a magnetic moment in the “−x” direction. A slight difference in thickness between the AP2 and AP1 layers produces a small net magnetic moment for the pinned layer 104 along the easy axis direction of the MR sensor to be patterned in a later step. In some embodiments, exchange coupling between the AP2 layer and the AP1 layer is facilitated by a coupling layer (made of, e.g., Ru, Rh, or Ir) with a thickness from 3 to 9 Angstroms. The AP1 reference layer 106 is also referred to as the inner pinned layer and may be a single layer or a composite layer. In some embodiments, the AP1 layer is amorphous in order to provide a more uniform surface on which to form a spacer or barrier layer 107. In some embodiments, the AP1 layer is made from CoFeB, CoFe, or a composite thereof, however, it can be made of any other suitable material as appreciated by those skilled in the art.

In some embodiments, a spacer or barrier layer 107 is formed above the SyAP pinned layer or AP1 reference layer 106. In some embodiments, the barrier layer 107 is an oxidized metal layer such as AlOx, MgO, AlTiOx, or TiOx. However, the spacer or barrier layer 107 can be made of any other suitable material as appreciated by those skilled in the art. In some embodiments, the barrier layer 107 can have a Mg/MgO/Mg configuration wherein a Mg layer (not shown) thick is deposited on the SyAP pinned layer. Then a ROX or natural oxidation (NOX) process is performed to oxidize the Mg layer. Subsequently, a second Mg layer is deposited on the oxidized Mg layer to result in a Mg/MgO/Mg barrier layer 107. In some embodiments, the first Mg layer is about 8 Angstroms thick and the second Mg layer is about 4 Angstroms. The RA and MR ratio for the MR sensor may be adjusted by varying the thickness of the two Mg layers in barrier layer 107 and by varying the natural oxidation time and pressure. Longer oxidation time and/or higher oxygen pressure will form a thicker MgO layer and increase the RA value.

In some embodiments, the free layer 108 is formed on the spacer or barrier layer 107. In some embodiments, the free layer 108 may comprise one or more of CoFeB CoFe, and NiFe and is magnetically aligned along the x-axis (pinned layer direction). The free layer 108, however, can be made of any other suitable material as appreciated by those skilled in the art. In some embodiments, the free layer may be a composite free layer. In some embodiments, the free layer 108 may be a composite CoFe/NiFe layer in which a CoFe layer with a thickness of about 5 to 15 Angstroms is formed on the tunnel barrier layer and a NiFe layer having a thickness between about 20 and 40 Angstroms is disposed on the CoFe layer. In some embodiments, a layer is formed between layers of CoFeB CoFe, and NiFe in the free layer 108.

In some embodiments, there is a capping layer 109 formed on the free layer 108. The capping layer 109 can be made of Ru, Ta, or a composite thereof. In some embodiments, the capping layer 41 has a thickness from about 60 to 250 Angstroms. Other capping layer materials may be used as appreciated by those skilled in the art.

In some embodiments, a composite hard mask 110 is disposed on the capping layer 109. In some embodiments, the composite hard mask structure 110 includes first sacrificial hard mask layer 111 and a second sacrificial hard mask layer 112, wherein the first sacrificial hard mask layer 111 and the second sacrificial hard mask layer 112 are not made from the same material. In some embodiments, the layers of the composite hard mask 110 are sequentially formed on the capping layer 109. In some embodiments, the first sacrificial hard mask layer 111 is the bottom layer of the composite hard mask structure 110 and disposed on the capping layer 109. The first sacrificial hard mask layer 111 is designed to serve as a chemical mechanical polishing (CMP) stop layer. In some embodiments, the second sacrificial hard mask layer 112 is the top layer of the composite hard mask structure 110 and disposed on the first sacrificial hard mask layer 111. The second sacrificial hard mask layer 112 is designed to prevent the CMP stop layer (the first sacrificial hard mask layer 111) from being damaged during photo process or photo rework processes.

In some embodiments, the first sacrificial hard mask layer 111 is composed of material that can be easily removed by a dry RIE or wet etch methods after a CMP process without affecting the capping layer 109. Due to the sensitivity of the capping layer 109, excessive sputter etching or CMP processing cannot be used after the removal of the first sacrificial hard mask layer 111 to prevent any damage to the MR sensor. The second sacrificial hard mask layer 112 is composed of material that can be removed by CMP or other etching methods without affecting the first sacrificial hard mask layer 111.

In some embodiments, the first sacrificial hard mask layer 111 comprises an amorphous carbon or silicon nitride masking layer. In some embodiments, the first sacrificial hard mask layer 111 is an amorphous carbon masking layer.

In some embodiments, the second sacrificial hard mask layer 112 comprises a silicon nitride, silicon oxide, metal, metal oxide, or metal nitride masking layer. In some embodiments, examples of the metal include Ti, Ta, NiCr, and NiFe. In some embodiments, examples of the metal oxide include TaOₓ, SmOₓ, Al₂O₃, and SiO₂. In some embodiments, an example of the metal nitride used is SiN. Other suitable material for the second sacrificial hard mask layer 112 may be used as appreciated by those skilled in the art.

In some embodiments, the composite hard mask 110 is made from C/SiO₂, C/NiFe, C/NiCr, C/SiN, C/SiON, C/Ti, C/Ru, C/TaOₓ, C/SmOₓ, SiN/Al₂O₃, or SiN/SiO₂ (first sacrificial hard mask layer 111/second sacrificial hard mask layer 112). In some embodiments, the thickness of the first sacrificial hard mask layer 111 is 10 to 150 Angstroms. In some embodiments, the thickness of the second sacrificial hard mask layer 112 is 20 to 800 Angstroms. In some embodiments, the thickness of the second sacrificial hard mask layer 112 is 20 to 750 Angstroms, 20 to 700 Angstroms, 20 to 650 Angstroms, 20 to 650 Angstroms, 20 to 550 Angstroms, 20 to 550 Angstroms, 20 to 500 Angstroms, 20 to 450 Angstroms, 20 to 400 Angstroms, 20 to 350 Angstroms, 20 to 300 Angstroms, 20 to 250 Angstroms, 20 to 200 Angstroms, 50 to 500 Angstroms, 50 to 450 Angstroms, 50 to 400 Angstroms, 50 to 350 Angstroms, 50 to 300 Angstroms, 50 to 250 Angstroms, or 50 to 200 Angstroms. In some embodiments, the thickness of the second sacrificial hard mask layer 112 is 200 to 800 Angstroms, 250 to 800 Angstroms, 300 to 800 Angstroms, 350 to 800 Angstroms, 400 to 800 Angstroms, 450 to 800 Angstroms, 500 to 800 Angstroms, 550 to 800 Angstroms, 600 to 800 Angstroms, 650 to 800 Angstroms, or 700 to 800 Angstroms. In some embodiments, the first sacrificial hard mask layer 111 is thinner than the thickness of the second sacrificial hard mask layer 112. In some preferred embodiments, the thickness of the first and second hard mask layers 111, 112 should be as thin as possible to minimize hard mask thickness requirement to pattern these layers.

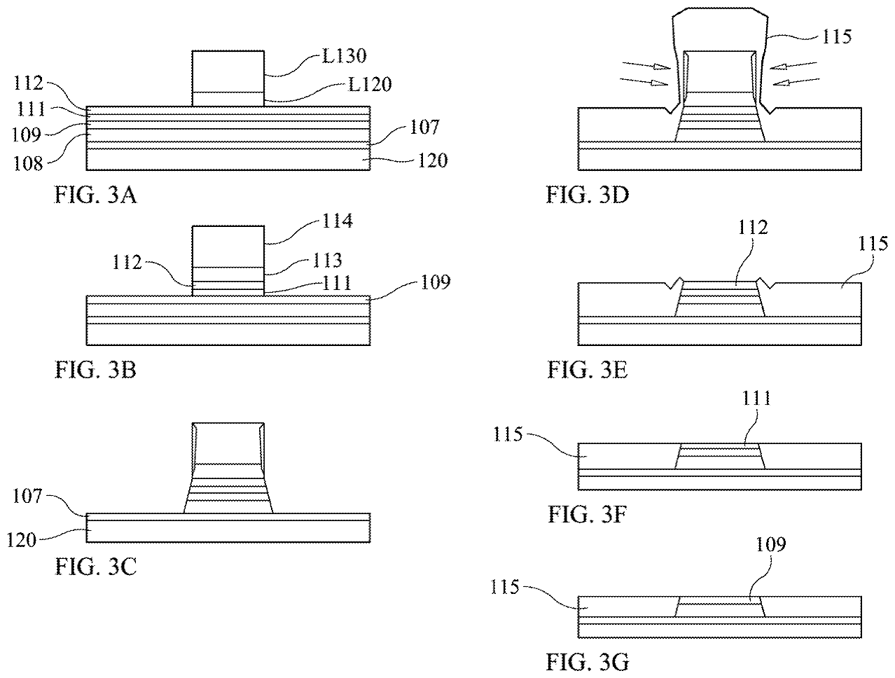

A method of forming a MR sensor is also described herein. FIG. 3(a)-(g) illustrates a method of forming a MR sensor according to some embodiments of the present disclosure. In some embodiments, the method includes providing the film stack structure 100 including the improved composite hard mask 110. In some embodiments, a bottom anti-reflective coating (BARC) 113 and a photoresist layer 114 are sequentially coated on the composite hard mask 110. In some embodiments, a MR junction photopatterning is performed. The photoresist layer is patterned to form an array of features that define the hard axis and easy axis dimensions of the MR sensor and achieve optimal critical dimension (CD) control. Then the photoresist pattern is transferred through the BARC by a dry RIE process as shown in FIG. 3(a).

In some embodiments, after BARC RIE, the first and second hard mask layers 111, 112 of the composite hard mask 100 are patterned by dry RIE, IBE, or a combination of both methods, as shown in FIG. 3(b). Because there is no photo undercut layer, the shape control of the hard mask for the MR sensor, e.g., TMR sensor, can be significantly improved. Without being bound to any particular theory, this improvement in the shape control of the hard mask allows for improvement of the tail length variation control.

In some embodiments, after etching of the first and second hard sacrificial mask layers 111, 112, a MR junction forming step is performed. The MR junction forming process includes ion beam etching (IBE) to pattern the MR sensor junction. It is essential in the MR junction forming process to be able to precisely and uniformly etch stop in one of the layers of the film stack 100, in particular etch stop between the seed layer 102 and the capping layer 109. In some embodiments, the etch stop at or within the spacer or barrier layer 107 as shown in FIG. 3(c). MR junction forming by ion beam etching (IBE) is believed to further improve pattern tail length control. The ion beam etching (IBE) can comprise both static and dynamic steps and the length of step is dependent on the hard mask structure and the magnetic film stack structures.

In some embodiments, after MR junction patterning a layer of insulating material 115 is deposited to insulate the MR junction from the surrounding environment. In some embodiments, after insulation layer deposition, ion beam etching (IBE) is performed to open up the sidewalls around the protruded pattern as shown in FIG. 3(d), thereby exposing the resist. In some embodiments, the ion beam etching IBE) is a high angle IBE. In some embodiments, once the resist pattern is exposed after IBE, e.g., high angle IBE, the BARC 113 and remaining photoresist 114 can be removed as shown in FIG. 3(e). In some embodiments, removing the BARC 113 and remaining photoresist 114 includes a liftoff process and an oxygen ashing process.

In some embodiments, after the liftoff process, a chemical mechanical polishing (CMP) is applied to planarize a wafer surface as shown in FIG. 3(f). The first sacrificial hard mask layer 111 is designed to serve as a chemical mechanical polishing (CMP) stop layer due to its low polishing rate relative to other deposited materials for formation of the MR device. In some embodiments, after chemical mechanical polishing (CMP), an etch back process is performed stopping on the top of the capping layer 109 as shown in FIG. 3(g). In some embodiments, the etch back process is a sputter etch process. In some embodiments, after the etch back process, any remaining residue of the first sacrificial hard mask layer 111 is removed. In some embodiments, removal of the remaining residue of the first sacrificial hard mask layer 111 can be done by oxygen ashing or a wet etch process. At this point, the wafer can be ready for top lead formation processes.

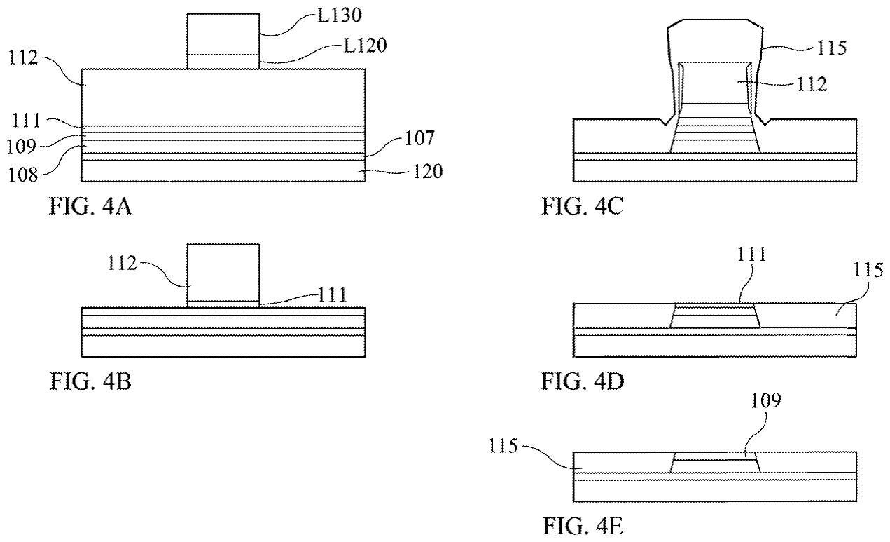

Another method of forming a MR sensor is also described herein. FIG. 4(a)-(e) illustrates a method of forming a MR sensor according to some embodiments of the present disclosure. In some embodiments, the method includes providing the film stack structure 100 including the improved composite hard mask 110. In some embodiments, the thickness of the first sacrificial hard mask layer 111 is 10 to 150 Angstroms. In some embodiments, the thickness of the second sacrificial hard mask layer 112 is 200 to 800 Angstroms, 250 to 800 Angstroms, 300 to 800 Angstroms, 350 to 800 Angstroms, 400 to 800 Angstroms, 450 to 800 Angstroms, 500 to 800 Angstroms, 550 to 800 Angstroms, 600 to 800 Angstroms, 650 to 800 Angstroms, or 700 to 800 Angstroms. In some embodiments, a bottom anti-reflective coating (BARC) 113 and a photoresist layer 114 are sequentially coated on the composite hard mask 110. In some embodiments, a MR junction photopatterning is performed. The photoresist layer is patterned to form an array of features that define the hard axis and easy axis dimensions of the MR sensor and achieve optimal critical dimension (CD) control. Then the photoresist pattern is transferred through the BARC by a dry RIE process a s shown in FIG. 4(a).

In some embodiments, after BARC RIE, the first and second hard mask layers 111, 112 of the composite hard mask 100 are patterned by dry RIE, IBE, or a combination of both methods. In some embodiments, the BARC 113 and remaining photoresist 114 can be removed after etching of the first and second hard mask layers 111, 112 as shown in FIG. 4(b). Removal of the BARC 113 and remaining photoresist 114 can be achieved by any suitable dry or wet etching process.

In some embodiments, after removing the BARC 113 and photoresist 114, a MR junction forming step is performed. The MR junction forming process includes ion beam etching (IBE) to pattern the MR sensor junction. It is essential in the MR junction forming process to be able to precisely and uniformly etch stop in one of the layers of the film stack 100, in particular etch stop between the seed layer 102 and the capping layer 109. In some embodiments, the etch stop at or within the spacer or barrier layer 107 as shown in FIG. 4(c). MR junction forming by ion beam etching (IBE) is believed to further improve pattern tail length control. The ion beam etching (IBE) can comprise both static and dynamic steps and the length of step is dependent on the hard mask structure and the magnetic film stack structures.

In some embodiments, after MR junction patterning a layer of insulating material 115 is deposited to insulate the MR junction from the surrounding environment. In some embodiments, after insulation layer deposition, ion beam etching (IBE) is performed to open up the sidewalls around the protruded pattern as shown in FIG. 4(c). In some embodiments, the ion beam etching IBE) is a high angle IBE.

In some embodiments, after ion beam etching, a chemical mechanical polishing (CMP) is applied to planarize a wafer surface as shown in FIG. 4(d). The first sacrificial hard mask layer 111 is designed to serve as a chemical mechanical polishing (CMP) stop layer due to its low polishing rate relative to other deposited materials for formation of the MR device. In some embodiments, after chemical mechanical polishing (CMP), an etch back process is performed stopping on the top of the capping layer 109. In some embodiments, the etch back process is a sputter etch process. In some embodiments, after the etch back process, any remaining residue of the first sacrificial hard mask layer 111 is removed. In some embodiments, removal of the remaining residue of the first sacrificial hard mask layer 111 can be done by oxygen ashing or a wet etch process. At this point, the wafer can be ready for top lead formation processes.

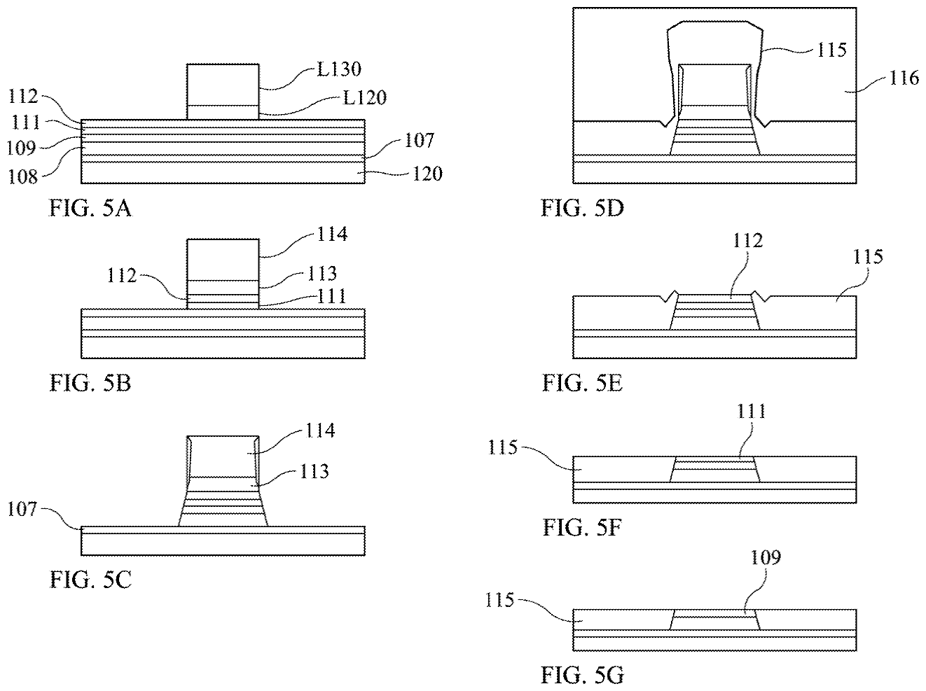

A third method of forming a MR sensor is also described herein. FIG. 5(a)-(g) illustrates a method of forming a MR sensor according to some embodiments of the present disclosure. In some embodiments, the method includes providing the film stack structure 100 including the improved composite hard mask 110. In some embodiments, a bottom anti-reflective coating (BARC) 113 and a photoresist layer 114 are sequentially coated on the composite hard mask 110. In some embodiments, a MR junction photopatterning is performed. The photoresist layer is patterned to form an array of features that define the hard axis and easy axis dimensions of the MR sensor and achieve optimal critical dimension (CD) control. Then the photoresist pattern is transferred through the BARC by a dry RIE process as shown in FIG. 5(a).

In some embodiments, after BARC RIE, the first and second hard mask layers 111, 112 of the composite hard mask 100 are patterned by dry RIE, IBE, or a combination of both methods, as shown in FIG. 5(b). Because there is no photo undercut layer, the shape control of the hard mask for the MR sensor, e.g., TMR sensor, can be significantly improved. Without being bound to any particular theory, this improvement in the shape control of the hard mask allows for improvement of the tail length variation control.

In some embodiments, after etching of the first and second hard sacrificial mask layers 111, 112, a MR junction forming step is performed. The MR junction forming process includes ion beam etching (IBE) to pattern the MR sensor junction. It is essential in the MR junction forming process to be able to precisely and uniformly etch stop in one of the layers of the film stack 100, in particular etch stop between the seed layer 102 and the capping layer 109. In some embodiments, the etch stop at or within the spacer or barrier layer 107 as shown in FIG. 5(c). MR junction forming by ion beam etching (IBE) is believed to further improve pattern tail length control. The ion beam etching (IBE) can comprise both static and dynamic steps and the length of step is dependent on the hard mask structure and the magnetic film stack structures.

In some embodiments, after MR junction patterning a layer of insulating material 115 is deposited to insulate the MR junction from the surrounding environment. In some embodiments, after insulation layer deposition, ion beam etching (IBE) is performed to open up the sidewalls around the protruded pattern as shown in FIG. 3(d), thereby exposing the resist. In some embodiments, the ion beam etching IBE) is a high angle IBE. In some embodiments, once the resist pattern is exposed after IBE, e.g., high angle IBE, a spin-on layer 116 is deposited. In some embodiments, the spin-on layer 116 is a planarization layer. The spin-on layer may include a spin-on carbon layer. The spin-on layer may include a spin-on organic polymer. The spin-on carbon layer may comprise an organic polymer having a carbon content in excess of 80 wt. %. In some embodiments, the spin-on carbon layer may comprise an organic polymer having a carbon content in excess of 90 wt. %. However, other suitable spin-on material can be used as appreciated by those skilled in the art.

In some embodiments, the BARC 113 and remaining photoresist 114 can be removed as shown in FIG. 5(e). In some embodiments, removal of the BARC 113 and remaining photoresist 114 can be achieved by any suitable dry or wet etching process. In some embodiments, removing the BARC 113 and remaining photoresist 114 includes a liftoff process and an oxygen ashing process.

In some embodiments, after removing the BARC 113 and photoresist 114, a chemical mechanical polishing (CMP) is applied to planarize a wafer surface as shown in FIG. 5(f). The first sacrificial hard mask layer 111 is designed to serve as a chemical mechanical polishing (CMP) stop layer due to its low polishing rate relative to other deposited materials for formation of the MR device. In some embodiments, after chemical mechanical polishing (CMP), an etch back process is performed stopping on the top of the capping layer 109 as shown in FIG. 5(g). In some embodiments, the etch back process is a sputter etch process. In some embodiments, after the etch back process, any remaining residue of the first sacrificial hard mask layer 111 is removed. In some embodiments, removal of the remaining residue of the first sacrificial hard mask layer 111 can be done by oxygen ashing or a wet etch process. At this point, the wafer can be ready for top lead formation processes.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof

We claim:

1. A composite hard mask, comprising:
a first sacrificial hard mask layer comprising an amorphous carbon or silicon nitride; and
a second sacrificial hard mask layer comprising a silicon nitride, silicon oxide, metal, metal oxide, or metal nitride,
wherein the first and second sacrificial hard mask layers are not made of the same material.

2. The composite hard mask of claim 1, wherein the first sacrificial hard mask layer is an amorphous carbon masking layer.

3. The composite hard mask of claim 1, wherein the first sacrificial hard mask layer is a silicon nitride masking layer.

4. The composite hard mask of claim 1, wherein the second sacrificial hard mask layer comprises Ti, Ta, NiCr, NiFe, TaOₓ, SmOₓ, Al₂O₃, SiO₂, or SiN.

5. The composite hard mask of claim 1, wherein the second sacrificial hard mask layer is made from material that can be removed without affecting the first sacrificial hard mask layer.

6. The composite hard mask of claim 1, wherein the first sacrificial hard mask layer comprises amorphous carbon and the second sacrificial hard mask layer comprises SiO₂, NiFe, NiCr, SiN, Ti, TaOₓ, or SmOₓ.

7. The composite hard mask of claim 1, wherein the first sacrificial hard mask layer comprises SiN and the second sacrificial hard mask layer comprises Al₂O₃, or SiO₂.

8. The composite hard mask of claim 1, wherein a thickness of the first sacrificial hard mask layer is 10 to 150 Angstroms.

9. The composite hard mask of claim 1, wherein a thickness of the second sacrificial hard mask layer is 20 to 800 Angstroms.

10. The composite hard mask of claim 1, wherein a thickness of the first sacrificial hard mask layer is less than a thickness of the second sacrificial hard mask layer.

11. A film stack structure, comprising:
the composite hard mask of claim 1.

12. The film stack structure of claim 11, further comprising a bottom electrode.

13. The film stack structure of claim 12, further comprising a seed layer, an anti-ferromagnetic (AFM) pinning layer, a ferromagnetic pinned layer, a coupling layer, a reference layer, a spacer or barrier layer, a ferromagnetic free layer, and a capping layer sequentially formed on the bottom electrode.

14. The film stack structure of claim 13, wherein the pinned layer, the coupling layer, and the reference layer 106 form a synthetic anti-parallel (SyAP) layer.

15. The film stack structure of claim 13, wherein the composite hard mask is formed on the capping layer.

16. A method of forming a MR sensor, comprising:
providing the film stack structure of claim 11.

17. The method of claim 16, further comprising sequentially coating a bottom anti-reflective coating (BARC) and a photoresist layer on the composite hard mask.

18. The method of claim 17, further comprising a MR junction photopatterning including patterning the photoresist layer and transferring a photoresist pattern through the BARC.

19. The method of claim 18, further comprising patterning the first and second hard mask layers by dry reactive ion etching (RIE), ion beam etching (IBE), or a combination of both methods.

20. The method of claim 19, further comprising forming a MR junction after patterning of the first and second hard sacrificial mask layers.

21. The method of claim 20, wherein forming the MR junction includes ion beam etching (IBE) to pattern the MR junction.

22. The method of claim 21, wherein ion beam etching (IBE) to pattern the MR junction stops between a seed layer and a capping layer of the film stack structure.

23. The method of claim 21, wherein ion beam etching (IBE) to pattern the MR junction stops at or within a spacer or barrier layer of the film stack structure.

24. The method of claim 20, further comprising depositing a layer of insulating material after forming the MR junction.

25. The method of claim 24, further comprising ion beam etching (IBE) after depositing the layer of insulating material to open up sidewalls around the MR junction and expose the photoresist layer.

26. The method of claim 25, further comprising removing the BARC and the photoresist layer.

27. The method of claim 26, further comprising applying a chemical mechanical polishing (CMP) process to planarize a wafer surface after removing the BARC and the photoresist layer.

28. The method of claim 27, wherein the first sacrificial hard mask layer is configured to serve as a CMP stop layer.

29. The method of claim 28, further comprising applying an etch back process to remove the first sacrificial hard mask layer.
